(19) United States
(12) Patent Application Publication
(10) Pub. No.: US 2023/0116213 A1
(43) Pub. Date: Apr. 13, 2023

(54) EXTREME ULTRAVIOLET MASK WITH CAPPING LAYER

(71) Applicant: Taiwan Semiconductor Manufacturing Co., Ltd., Hsinchu (TW)

(72) Inventors: Wei-Hao LEE, Hsinchu (TW); Pei-Cheng HSU, Hsinchu (TW); Hsin-Chang LEE, Hsinchu (TW)

(21) Appl. No.: 17/745,562

(22) Filed: May 16, 2022

Related U.S. Application Data
(60) Provisional application No. 63/254,796, filed on Oct. 12, 2021.

(51) Int. Cl. G03F 1/24; H01L 21/033; G03F 7/20

(52) U.S. Cl. CPC G03F 1/24; H01L 21/0337; G03F 7/70958; G03F 7/70033

(57) ABSTRACT

An extreme ultraviolet (EUV) mask, includes a substrate, a reflective multilayer stack on the substrate, and a multi-layer capping feature on the reflective multilayer stack. The multi-layer capping feature includes a first capping layer including a material containing an element having a first carbon solubility and a second capping layer including a material containing an element having a second carbon solubility. The first carbon solubility being different from the second carbon solubility. In some embodiments an element of the material of the first capping layer and an element of the second capping layer have extinction coefficients for EUV having a wavelength of 13.5 nm that are different.

### PRIORITY CLAIM AND CROSS-REFERENCE

This application claims the benefit of U.S. Provisional Patent Application No. 63/254,796, filed Oct. 12, 2021, which is incorporated by reference herein in its entirety.

### BACKGROUND

The semiconductor industry has experienced exponential growth. Technological advances in materials and design have produced generations of integrated circuits (ICs), where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs.

Photolithography may be used to form the components or lines on a semiconductor wafer. One example of a photolithographic technique utilizes extreme ultraviolet (EUV) energy and a patterned absorber layer of an EUV mask.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of an extreme ultraviolet (EUV) mask, in accordance with a first embodiment.

FIG. 2 is a flowchart of a method for fabricating the EUV mask of FIG. 1, in accordance with some embodiments.

FIGS. 3A-3L are cross-sectional views of an EUV mask at various stages of the fabrication process of FIG. 2, in accordance with some embodiments.

FIG. 4 is a cross-sectional view of an extreme ultraviolet (EUV) mask, in accordance with a second embodiment.

FIG. 5 is a flowchart of a method for fabricating the EUV mask of FIG. 4, in accordance with some embodiments.

FIGS. 6A-6L are cross-sectional views of an EUV mask at various stages of the fabrication process of FIG. 5, in accordance with some embodiments.

FIG. 7 is a flowchart of a method of using and EUV mask in accordance with some embodiments.

FIG. 8 is a flowchart of a method of using and EUV mask in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the manufacture of integrated circuits (ICs), patterns representing different layers of the ICs are fabricated using a series of reusable photomasks (also referred to herein as photolithography masks or masks) in order to transfer the design of each layer of the ICs onto a semiconductor substrate during the semiconductor device fabrication process.

With the shrinkage in IC size, extreme ultraviolet (EUV) light, for example, with a wavelength of 13.5 nm is employed in a lithographic process to enable transfer of very small patterns (e.g., nanometer-scale patterns) from a mask to a semiconductor wafer. Because most materials are highly absorbing at the wavelength of 13.5 nm, EUV lithography utilizes a reflective-type EUV mask having a reflective multilayer to reflect the incident EUV light and an absorber layer on top of the reflective multilayer to absorb radiation in areas where light is not supposed to be reflected by the mask. The reflective multilayer and absorber layer are on a low thermal expansion material substrate. The reflective multilayer reflects the incident EUV light and the patterned absorber layer on top of the reflective multilayer absorbs light in areas where light is not supposed to be reflected by the mask. The mask pattern is defined by the absorber layer and is transferred to a semiconductor wafer by reflecting EUV light off portions of a reflective surface of the EUV mask.

An ongoing desire to have more densely packed integrated devices has resulted in changes to the photolithography process in order to form smaller individual feature sizes. The minimum feature size or “critical dimension” (CD) obtainable by a process is determined approximately by the formula CD=k₁*λ/NA, where k₁ is a process-specific coefficient, λ, is the wavelength of applied light/energy, and NA is the numerical aperture of the optical lens as seen from the substrate or wafer.

The present disclosure describes various embodiments of an EUV mask that exhibits a resistance to carbon contamination. Carbon contamination can negatively affect the critical dimension of features formed in an absorber layer and a capping feature of the EUV mask. For example, some materials used as a capping layer may have many free radicals that can react with carbon atoms near the EUV mask surface during exposure to EUV energy. During exposure, hydrocarbon molecules near the surface of the EUV mask can be cracked when exposed to high energy and deposit onto exposed surfaces (e.g., sidewalls and bottoms or trenches) of the EUV mask. Cracking of the hydrocarbon molecules can produce carbon atoms that can react with the free radicals. It has been observed that carbon deposits to greater thicknesses on exposed surfaces of the mask that are near the center of the mask compared to exposed surfaces of the mask that are near edges of the mask. In some embodiments, the amount of carbon that forms on the exposed surfaces near the center of the mask is three times as thick as the carbon that forms on exposed surfaces near the edges of the mask. The hydrocarbons may originate from numerous sources, including outgassing from materials within the EUV tool, such as structures of the tool, photoresists or hard masks used in the tool. The resulting carbon atoms or carbon containing molecules react with or are absorbed by materials they come in contact with and build up on surfaces of the EUV mask. The buildup of carbon on surfaces of the EUV mask, e.g., surfaces of the capping layer, can negatively affect the ability of the EUV mask to pattern features on a substrate that meet critical dimension criteria, such as critical dimension uniformity (CDU). For example, carbon absorbs EUV wavelengths to a greater degree than other materials making up an EUV mask. Thus, when unwanted carbon is present on an EUV mask, the exposure energy or amount of incident EUV energy needed to achieve a desired level of EUV radiation reflected from the mask is greater than when the unwanted carbon is not present. In some embodiments, depending on the critical dimension of the features on the wafer and the critical dimensions of the features on the mask, the exposure energy needed when carbon is present on the EUV mask can be 10% or more than when carbon is not present on the EUV mask. This need for increased exposure energy will increase the cost of the energy required to effectively expose the wafer or will increase the length of time needed to achieve a desired level of exposure.

Embodiments in accordance with the present disclosure broadly provide a photolithography mask that includes a multi-layered capping feature on the mask. In some embodiments, the multi-layered capping feature includes multiple layers of capping materials. In some examples, the material used for one capping layer of the multilayered capping feature is different in composition from the material used for another capping layer of the multilayered capping feature. In some embodiments, the material of one capping layer exhibits a carbon solubility property that is different from a carbon solubility property of the material of another capping layer of the multilayered capping feature. For example, in some embodiments, a multilayered capping feature is provided that includes a first capping layer formed of a material including an element having a first carbon solubility property. The multilayered capping feature includes at least another capping layer formed of a material including an element having a second carbon solubility property that is different from the first carbon solubility property of the element of the material of the first capping layer. The carbon solubility property is an indication of the material of a capping layer propensity to react with, retain, attract or absorb carbon atoms or carbon containing molecules. When the carbon atoms are attracted to and retained or absorbed by or react with the material of the capping layer they build up and contaminate the capping layer. In some embodiments, the carbon build up or contamination completely covers the capping layer. In other embodiments, the carbon build up or contamination partially covers the capping layer. The combination of the layer of carbon contamination and the capping layer has dimensions that are different from the dimensions of the capping layer without the carbon contamination. Such changes in dimension and/or changes in the incident EUV energy needed to produce a desired intensity of reflected EUV energy causes the negative issues described in the previous paragraph. In accordance with embodiments of the present disclosure, a multi-layered capping layer including multiple individual capping layers is employed to protect EUV masks from carbon buildup or contamination on surfaces of the EUV mask. The materials of the capping layers formed in accordance with the present disclosure reduce the susceptibility of the multilayered capping feature to contamination with hydrocarbon molecules or carbon atoms.

In embodiments of the present disclosure, an EUV mask includes a multilayered capping feature that includes at least one capping layer that includes a material containing an element having a low solid carbon solubility. An element that has a low solid carbon solubility is characterized by a maximum carbon solubility in the solid phase of the element that is in equilibrium with the liquid phase of the element at the eutectic point of the element that is less than about 3 atomic percent. Examples of elements having a low atomic percent solid carbon solubility include, but are not limited to, elements that have a solid carbon solubility that is less than about 3 atomic percent. For example, in some embodiments, materials of a capping layer contain elements that do not have a carbon solubility that is less than about 3 atomic percent, yet still provide a resistance to carbon buildup or contamination on the surface of the material. Elements having low solid carbon solubility that are useful in embodiments of the present disclosure are alternatively characterized by an effective solid carbon solubility in the element at 1000° C. of less than 1.6. The effective solid carbon solubility in the element at 1000° C. is obtained by multiplying the eutectic point solid carbon solubility value by 1000° C. /melting point of the element. In accordance with some embodiments, element(s) of the material of one capping layer have a carbon solubility that is different from element(s) of the material of another capping layer forming the multilayered capping feature. In some embodiments, the material of at least one layer of the multilayered capping feature includes a material including an element that has an EUV extinction coefficient for EUV radiation having a wavelength of 13.5 nm that is greater than or less than an EUV extinction coefficient for EUV radiation having a wavelength of 13.5 nm of an element of a material of another layer of the multilayered capping feature. When the individual capping layers of the multilayered capping feature include elements that have differing EUV extinction coefficients for EUV radiation having a wavelength of 13.5 nm, the amount of incident EUV energy absorbed in one capping layer is different from the EUV energy absorbed in another capping layer of the multilayered capping feature. For example, in some embodiments, the material of one capping layer includes an element having an EUV extinction coefficient for EUV radiation having a wavelength of 13.5 nm between 0.96 and 0.87 and the material of another capping layer includes an element having an EUV extinction coefficient for EUV radiation having a wavelength of 13.5 nm different from the EUV extinction coefficient of the one capping layer. Materials include elements having an EUV extinction coefficient for EUV radiation having a wavelength of 13.5 nm between 0 and 0.1 do not reduce the transmission of EUV energy by an amount that requires that the level of incident EUV energy be increased by an undesirable amount. The materials for use in capping layers of the multilayered capping features in accordance with the present embodiments, should not absorb so much EUV energy that the amount of EUV energy incident on the EUV mask needs to be increased or the exposure time needs to be increased an undesirable amount. In addition, the materials for use in capping layers of the multilayered capping features in accordance with the present embodiment exhibit good adhesion to each other as well as materials upon which the capping layers are deposited or with materials that are deposited onto the capping layers. In some embodiments, the multilayered capping feature includes at least one layer including chromium (Cr), rhodium (Rh), zinc (Zn), zirconium (Zr), silver (Ag), cadmium (Cd) or alloys thereof. Examples of alloys of Cr, Rh, Zn, Zr, Ag or Cd include CrRh, CrZn, CrZr, CrAg, CrCd, RhZr, RhZn, RhAg, RhCd, ZnZr, ZnAg, ZnCd, ZrAg, ZrCd or AgCd. In other embodiments, the multilayered capping feature includes at least one layer including Cr, Rh, Zr, Ag, Cd or alloys thereof. In other embodiments, the multilayered capping feature includes at least one layer including Cu, Ir, Pt and Pd or alloys thereof. In some embodiments the multilayered capping feature includes at least one layer that includes a material containing an element having an index of refraction of greater than 0.87 and less than 0.971. Examples of materials including an element having an index of refraction of greater than 0.87 and less than 0.97 include, but are not limited to the materials described in this paragraph.

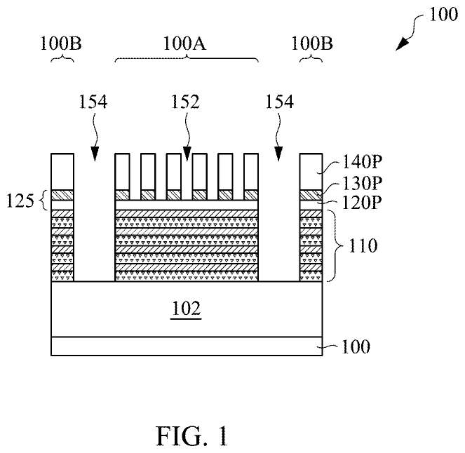

FIG. 1 is a cross-sectional view of an EUV mask 100, in accordance with a first embodiment of the present disclosure. Referring to FIG. 1, the EUV mask 100 includes a substrate 102, a reflective multilayer stack 110 over a front surface of the substrate 102, a multilayered capping feature 125 over the reflective multilayer stack 110 that includes a first patterned capping layer 120P and a second patterned capping layer 130P over the first patterned capping layer 120P, and a patterned absorber layer 140P over the multilayered capping feature 125. The EUV mask 100 further includes a conductive layer 104 over a back surface of the substrate 102 opposite the front surface. While the embodiment of FIG. 1 is illustrated and described with reference to a multilayered capping feature 125 that includes two capping layers, embodiments of the present disclosure include EUV masks that include a multilayered capping feature including more than two capping layers, e.g., three, four, five or more capping layers.

The patterned absorber layer 140P and the patterned second capping layer 130P contain a pattern of openings 152 that correspond to circuit patterns to be formed on a semiconductor wafer. The pattern of openings 152 is located in a pattern region 100A of the EUV mask 100, exposing a surface of the first capping layer 120P. The pattern region 100A is surrounded by a peripheral region 100B of the EUV mask 100. The peripheral region 100B corresponds to a non-patterned region of the EUV mask 100 that is not used in an exposing process during IC fabrication. In some embodiments, the pattern region 100A of EUV mask 100 is located at a central region of the substrate 102, and the peripheral region 100B is located at an edge portion of the substrate 102. The pattern region 100A is separated from the peripheral region 100B by trenches 154. The trenches 154 extend through the patterned absorber layer 140P, the second patterned capping layer 130P, the first patterned capping layer 120P, and the reflective multilayer stack 110, exposing the front surface of the substrate 102.

In accordance with some embodiments of the present disclosure, patterned absorber layer 140P is a layer of absorber material that is an alloy of a transition metal, e.g., tantalum (Ta), ruthenium (Ru), chromium (Cr), platinum (Pt), gold (Au), iridium (Ir), titanium (Ti), niobium (Nb), rhodium (Rh), molybdenum (Mo), tungsten (W), or palladium (Pd), and at least one alloying element selected from ruthenium (Ru), chromium (Cr), tantalum (Ta), platinum (Pt), palladium (Pd), tungsten (W), gold (Au), iridium (Ir), titanium (Ti), niobium (Nb), rhodium (Rh), molybdenum (Mo), hafnium (Hf), boron (B), nitrogen (N), oxygen (O), silicon (Si), zirconium (Zr), or vanadium (V).

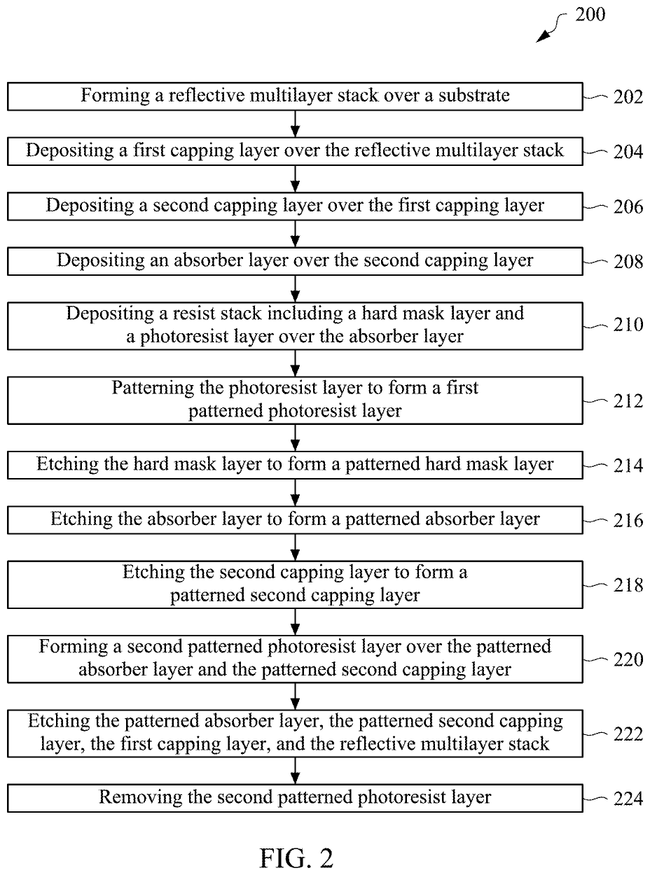

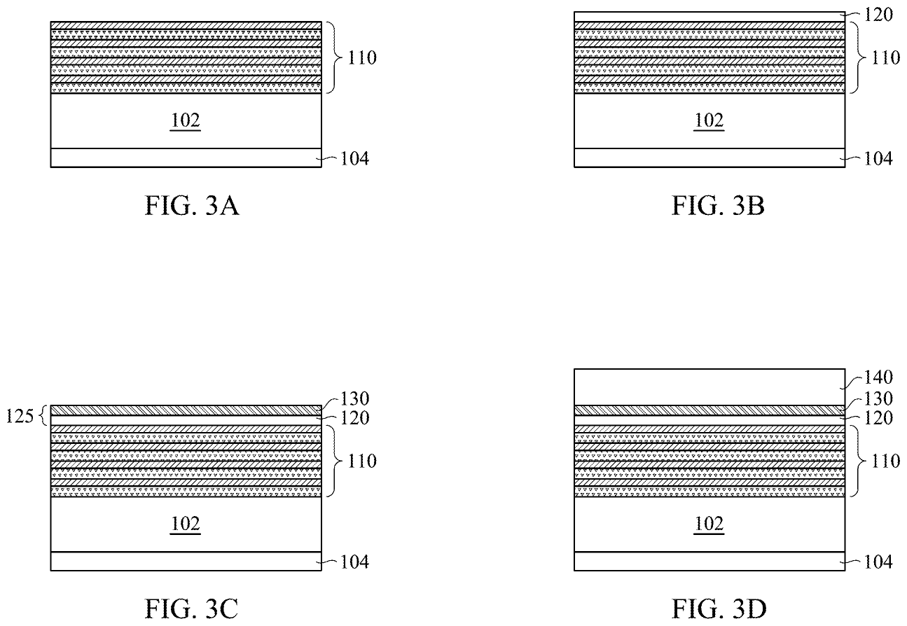

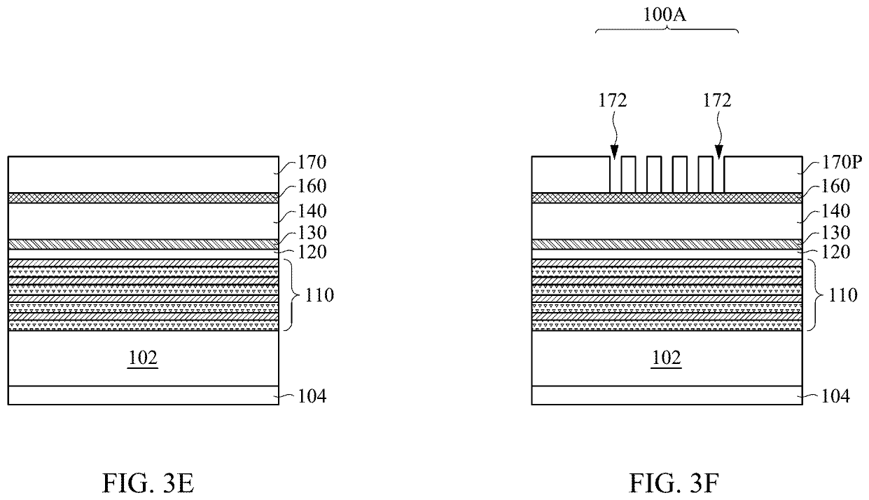

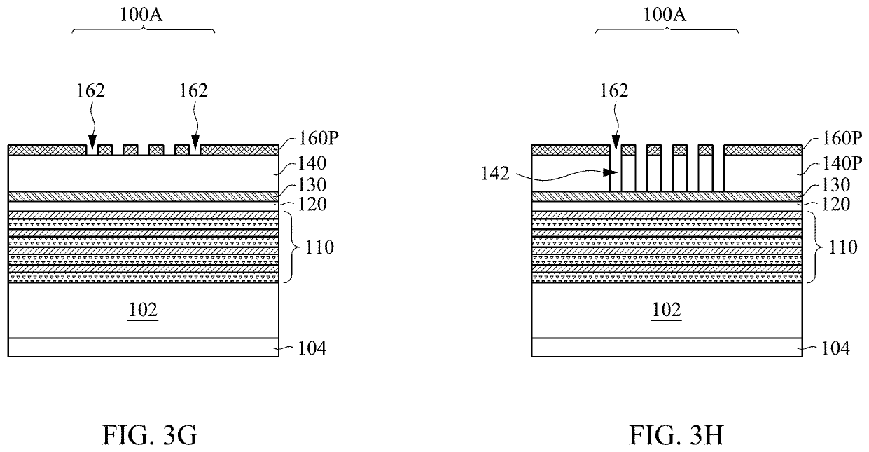

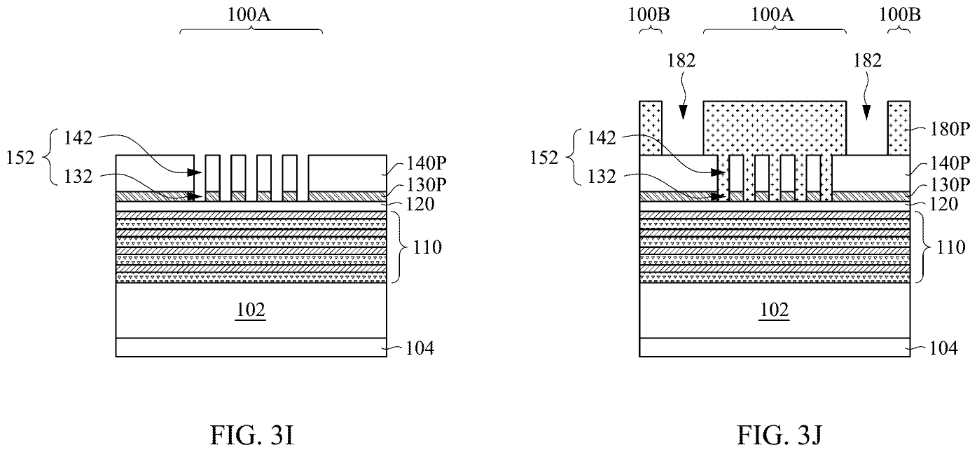

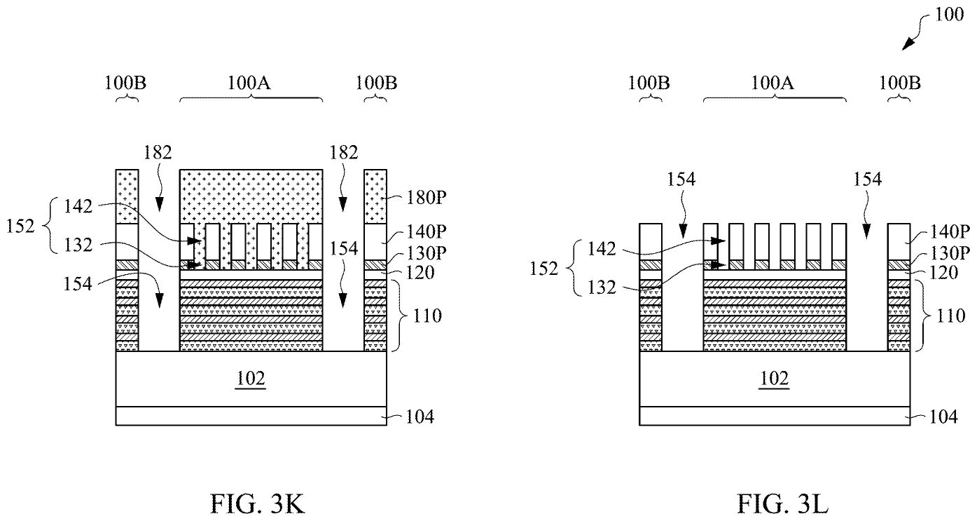

FIG. 2 is a flowchart of a method 200 for fabricating an EUV mask in accordance with an embodiment of the present disclosure, for example, EUV mask 100. FIG. 3A through FIG. 3L are cross-sectional views of the EUV mask 100 at various stages of the fabrication process, in accordance with some embodiments. The method 200 is discussed in detail below, with reference to the EUV mask 100. In some embodiments, additional operations are performed before, during, and/or after the method 200, or some of the operations described are replaced and/or eliminated. In some embodiments, some of the features described below are replaced or eliminated. One of ordinary skill in the art would understand that although some embodiments are discussed with operations performed in a particular order, these operations may be performed in another logical order.

Referring to FIGS. 2 and 3A, the method 200 includes operation 202, in which a reflective multilayer stack 110 is formed over a substrate 102, in accordance with some embodiments. FIG. 3A is a cross-sectional view of an initial structure of an EUV mask 100 after forming the reflective multilayer stack 110 over the substrate 102, in accordance with some embodiments.

Referring to FIG. 3A, the initial structure of the EUV mask 100 includes a substrate 102 made of glass, silicon, quartz, or other low thermal expansion materials. The low thermal expansion material helps to minimize image distortion due to mask heating during use of the EUV mask 100. In some embodiments, the substrate 102 includes fused silica, fused quartz, calcium fluoride, silicon carbide, black diamond, or titanium oxide doped silicon oxide (SiO₂/TiO₂). In some embodiments, the substrate 102 has a thickness ranging from about 1 mm to about 7 mm. If the thickness of the substrate 102 is too small, a risk of breakage or warping of the EUV mask 100 increases, in some instances. On the other hand, if the thickness of the substrate is too great, a weight and cost of the EUV mask 100 is needlessly increased, in some instances.

In some embodiments, a conductive layer 104 is disposed on a back surface of the substrate 102. In some embodiments, the conductive layer 104 is in direct contact with the back surface of the substrate 102. The conductive layer 104 is adapted to provide for electrostatically coupling of the EUV mask 100 to an electrostatic mask chuck (not shown) during fabrication and use of the EUV mask 100. In some embodiments, the conductive layer 104 includes chromium nitride (CrN) or tantalum boride (TaB). In some embodiments, the conductive layer 104 is formed by a deposition process such as, for example, chemical vapor deposition (CVD), plasma-enhanced chemical vapor deposition (PECVD), or physical vapor deposition (PVD). The thickness of the conductive layer 104 is controlled such that the conductive layer 104 is optically transparent.

The reflective multilayer stack 110 is disposed over a front surface of the substrate 102 opposite the back surface. In some embodiments, the reflective multilayer stack 110 is in direct contact with the front surface of the substrate 102. The reflective multilayer stack 110 provides a high reflectivity to the EUV light. In some embodiments, the reflective multilayer stack 110 is configured to achieve about 60% to about 75% reflectivity at the peak EUV illumination wavelength, e.g., the EUV illumination at 13.5 nm. Specifically, when the EUV light is applied at an incident angle of 6° to the surface of the reflective multilayer stack 110, the maximum reflectivity of light in the vicinity of a wavelength of 13.5 nm is about 60%, about 62%, about 65%, about 68%, about 70%, about 72%, or about 75%.

In some embodiments, the reflective multilayer stack 110 includes alternatively stacked layers of a high refractive index material and a low refractive index material. A material having a high refractive index has a tendency to scatter EUV light on the one hand, and a material having a low refractive index has a tendency to transmit EUV light on the other hand. Pairing these two type materials together provides a resonant reflectivity. In some embodiments, the reflective multilayer stack 110 includes alternatively stacked layers of molybdenum (Mo) and silicon (Si). In some embodiments, the reflective multilayer stack 110 includes alternatively stacked Mo and Si layers with Si being in the topmost layer. In some embodiments, a molybdenum layer is in direct contact with the front surface of the substrate 102. In some other embodiments, a silicon layer is in direct contact with the front surface of the substrate 102. Alternatively, the reflective multilayer stack 110 includes alternatively stacked layers of Mo and beryllium (Be).

The thickness of each layer in the reflective multilayer stack 110 depends on the EUV wavelength and the incident angle of the EUV light. The thickness of alternating layers in the reflective multilayer stack 110 is tuned to maximize the constructive interference of the EUV light reflected at each interface and to minimize the overall absorption of the EUV light. In some embodiments, the reflective multilayer stack 110 includes from 30 to 60 pairs of alternating layers of Mo and Si. Each Mo/Si pair has a thickness ranging from about 2 nm to about 7 nm, with a total thickness ranging from about 100 nm to about 300 nm. In some embodiments, the thickness of the alternating layers in the reflective multilayer stack 110 are different.

In some embodiments, each layer in the reflective multilayer stack 110 is deposited over the substrate 102 and underlying layer using ion beam deposition (IBD) or DC magnetron sputtering. The deposition method used helps to ensure that the thickness uniformity of the reflective multilayer stack 110 is better than about 0.85 across the substrate 102. For example, to form a Mo/Si reflective multilayer stack 110, a Mo layer is deposited using a Mo target as the sputtering target and an argon (Ar) gas (having a gas pressure of from 1.3×10⁻² Pa to 2.7×10⁻² Pa) as the sputtering gas with an ion acceleration voltage of from 300 V to 1,500 Vat a deposition rate of from 0.03 to 0.30 nm/sec and then a Si layer is deposited using a Si target as the sputtering target and an Ar gas (having a gas pressure of 1.3×10⁻² Pa to 2.7×10⁻² Pa) as the sputtering gas, with an ion acceleration voltage of from 300 V to 1,500 V at a deposition rate of from 0.03 to 0.30 nm/sec. By stacking Si layers and Mo layers in 40 to 50 cycles, each of the cycles comprising the above steps, the Mo/Si reflective multilayer stack is deposited.

Referring to FIGS. 2 and 3B, the method 200 proceeds to operation 204, in which a first capping layer 120 is deposited over the reflective multilayer stack 110, in accordance with some embodiments. FIG. 3B is a cross-sectional view of the structure of FIG. 3A after depositing the first capping layer 120 over the reflective multilayer stack 110, in accordance with some embodiments.

Referring to FIG. 3B, the first capping layer 120 (of the multilayered capping feature 125 in FIGS. 1 and 3C) is disposed over the topmost surface of the reflective multilayer stack 110. As described herein, the first capping layer 120 includes a material with low carbon solubility which serves to prevent or reduce the amount of carbon contamination of the mask.

In some embodiments, the first capping layer 120 includes a material that is less susceptible to carbon contamination compared to conventional materials used as capping layers. Examples of such materials include materials having a low carbon solubility at 1000° C., e.g., a carbon solubility at 1000° C. that is less than about 1.6 atomic percent. Examples of materials having a low atomic percent carbon solubility at 1000° C. include, but are not limited to, materials that have a carbon solubility in 1000° C. that is less than about 1.6 atomic percent. Other examples of materials having a low atomic percent carbon solubility at 1000° C. include, but are not limited to materials that have a carbon solubility at 1000° C. that is less than about 1.3 atomic percent. In some embodiments, the material of the first capping layer 120 has a carbon solubility at 1000° C. that is different from the material of the second capping layer 130. For example, the carbon solubility of the material of the first capping layer 120 is less than or greater than the carbon solubility of the material of the second capping layer 130. For example, in some embodiments, materials of a capping layer do not have a carbon solubility that is less than about 1.6 atomic percent or 1.3 atomic percent, yet still provide a resistance to carbon buildup or contamination on the surface of the material. In accordance with some embodiments, the material of one capping layer has a carbon solubility that is different from the material of another capping layer forming the multilayered capping feature. In some embodiments in accordance with FIG. 1, the material of the first capping layer 120 has an EUV extinction coefficient that is greater than an EUV extinction coefficient of a material of another layer of the multilayered capping feature 125. In some embodiments in accordance with FIG. 1, the material of the first capping layer 120 has an EUV extinction coefficient for EUV radiation having a wavelength of 13.5 nm that is less than an EUV extinction coefficient for EUV radiation having a wavelength of 13.5 nm of a material of another layer of the multilayered capping feature 125. For example, the first capping layer 120 of the multilayered capping feature 125 includes a material that has an EUV extinction coefficient for EUV radiation having a wavelength of 13.5 nm between 0 and 0.1. In other embodiments, the material of the first capping layer includes an element having an EUV extinction coefficient for EUV radiation having a wavelength of 13.5 nm between 0 and 0.08, between 0 and 0.06, between 0 and 0.04 or between 0 and 0.04. Materials that have an EUV extinction coefficient for EUV radiation having a wavelength of 13.5 nm within the ranges described above do not reduce the transmission of EUV energy by an amount that requires that the level of incident EUV energy be increased by an undesirable amount. The materials for use in capping layers of the multilayered capping features in accordance with the present embodiments, should not absorb so much EUV energy that the amount of EUV energy incident on the EUV mask needs to be increased or the exposure time needs to be increased an undesirable amount. In addition, the materials for use in capping layers of the multilayered capping features in accordance with the present embodiment exhibit good adhesion to each other as well as materials upon which the capping layers are deposited or with materials that are deposited onto the capping layers. In some embodiments, the multilayered capping feature 125 includes at least one layer 120 including Cr, Rh, Zn, Zr, Ag, Cd or alloys thereof. For example first capping layer 120 can include chromium nitride (CrN), Zinc nitride (Zn₃N₂) or zirconium nitride (ZrN). In other embodiments, the multilayered capping feature 125 includes at least one layer 120 including Cr, Rh, Zr, Ag, Cd or alloys thereof. In other embodiments, the multilayered capping feature 125 includes at least one layer 120 including Cu, Ir, Pt and Pd or alloys thereof. In accordance with embodiments of the present disclosure, carbides of the elements described above are undesirable for use as a material for first capping layer 120 because carbon atoms from the carbide can diffuse into lower layer during heat treatment thereof. In some embodiments the multilayered capping feature 125 includes at least one layer 120 that includes a material having an index of refraction for EUV radiation having a wavelength of 13.5 nm of less than 0.97. In some embodiments the multilayered capping feature 125 includes at least one layer 120 that includes a material having an index of refraction for EUV radiation having a wavelength of 13.5 nm that is greater than 0.87. Examples of materials having an index of refraction for EUV radiation having a wavelength of 13.5 nm of less than 0.97 or greater than 0.87 include, but are not limited to the materials described above in this paragraph. In some embodiments, the first capping layer 120 has a thickness ranging from about 0.5 to 5 nm. First capping layer 120 having a thickness ranging from about 0.5 to 5 nm has a thickness that is sufficient to prevent or reduce carbon contamination while not being so thick as to reduce EUV transmission by an undesired amount. Embodiments in accordance with the present disclosure are not limited to EUV masks that include a first capping layer 120 that has a thickness from 0.5 to about 5 nm. Embodiments in accordance with the present disclosure include EUV masks that include a first capping layer 120 that has a thickness less than 0.5 nm and EUV masks that have a first capping layer 120 that has a thickness greater than about 5 nm.

In some embodiments, the first capping layer 120 is formed using a deposition process such as, for example, IBD, chemical vapor deposition (CVD), physical vapor deposition (PVD), atomic layer deposition (ALD) thermal ALD, PE-ALD, PECVD, E-beam evaporation, thermal evaporation, ion beam induced deposition, sputtering, electrodeposition, or electroless deposition.

Referring to FIGS. 2 and 3C, the method 200 proceeds to operation 206, in which a second capping layer 130 is deposited over the first capping layer 120, in accordance with some embodiments. FIG. 3C is a cross-sectional view of the structure of FIG. 3B after depositing the second capping layer 130 over the capping layer 120, in accordance with some embodiments. In the embodiment of FIG. 3C, first capping layer 120 and second capping layer 130 comprise the multilayered capping feature 125.

Referring to FIG. 3C, the second capping layer 130 is disposed on the first capping layer 120. In some embodiments, the second capping layer 130 possesses different etching characteristics from an absorber layer subsequently formed thereon, and thereby may serves as an etch stop layer to prevent damages to the capping layer 120 during patterning of an absorber layer. Further, the second capping layer 130 may also serve later as a sacrificial layer for focused ion beam repair of defects in the absorber layer. In some embodiments the second capping layer 130 includes a material including an element having an extinction coefficient κ ranging between 0 and 0.1 and a refractive index n between 0.87 and 0.97 relative to EUV wavelengths. In other embodiments the second capping layer 130 includes a material including an element having an extinction coefficient κ ranging between 0 and 0.08, between 0 and 0.06, between 0 and 0.04 or between 0 and 0.021. With a material having an extinction coefficient κ and a refractive index n in these ranges, the material of the second capping layer 130 is able to transmit a desired level of incident EUV light and not affect the phase of the incident EUV light in an undesirable way.

In some embodiments, the second capping layer 130 includes ruthenium (Ru), niobium (Nb), silicon (Si), chromium (Cr) or alloys of these materials. Specific examples of materials used for second capping layer 130 include ruthenium niobium (RuNb) ruthenium boride (RuB), ruthenium silicide (RuSi), ruthenium dioxide (RuO₂), ruthenium niobium oxide (RuNbO), niobium pentoxide (Nb₂O₅), silicon nitride (SiN), silicon oxynitride (SiON), chromium oxide (CrO), chromium nitride (CrN) or chromium oxynitride (CrON). In some other embodiments, the second capping layer 130 includes a dielectric material such as, for example, silicon oxide. In some embodiments, the second capping layer 130 is deposited by thermal ALD, PE-ALD, CVD, PECVD, PVD E-beam evaporation, thermal evaporation, ion beam induced deposition, sputtering, electrodeposition, or electroless deposition. In some embodiments, the second capping layer has a thickness ranging from about 0.5 to 5 nm. Second capping layer 130 having a thickness ranging from about 0.5 to 5 nm has a thickness that is sufficient to protect the underlying first capping layer 120 and/or multilayer stack 110 from oxidation or chemical etchants during the mask formation process or semiconductor process using the mask. When second capping layer 130 is 0.5 to 5 nm thick it is not so thick as to reduce EUV transmission by an undesired amount. Embodiments in accordance with the present disclosure are not limited to EUV masks that include a second capping layer 130 that has a thickness from 0.5 to about 5 nm. Embodiments in accordance with the present disclosure include EUV masks that include a second capping layer 130 that has a thickness less than 0.5 nm and EUV masks that have a second capping layer 130 that has a thickness greater than about 5 nm.

In some embodiments, the material of the second capping layer 130 has a carbon solubility at 1000° C. that is different from the material of the first capping layer 120. For example in some embodiments, the carbon solubility of the material of the second capping layer 130 is greater than the carbon solubility of the material of the first capping layer 120. In accordance with some embodiments of FIG. 1, the material of the second capping layer 130 has an EUV extinction coefficient that is less than an EUV extinction coefficient of a material of another layer, e.g., first capping layer 120 of the multilayered capping feature 125. In other embodiments of FIG. 1, the material of the second capping layer 130 has an EUV extinction coefficient for EUV radiation having a wavelength of 13.5 nm that is greater than an EUV extinction coefficient for EUV radiation having a wavelength of 13.5 nm of a material of the first capping layer 120 of the multilayered capping feature 125. In addition, the materials for use in second capping layer 130 of the multilayered capping features in accordance with the present embodiment exhibit good adhesion to first capping layer 120, as well as materials which are deposited onto the second capping layer 130.

Referring to FIGS. 2 and 3D, the method 200 proceeds to operation 208, in which an absorber layer 140 is deposited over the second capping layer 130, in accordance with various embodiments. FIG. 3D is a cross-sectional view of the structure of FIG. 3C after depositing the absorber layer 140 over the second capping layer 130, in accordance with some embodiments.

Referring to FIG. 3D, the absorber layer 140 is disposed in direct contact with the second capping 130. The absorber layer 140 is usable to absorb radiation in the EUV wavelength projected onto the EUV mask 100.

The absorber layer 140 includes an absorber material having a high extinction coefficient κ and a low refractive index n for EUV wavelengths. In some embodiments, the absorber layer 140 includes an absorber material having a high extinction coefficient and a low refractive index at 13.5 nm wavelength. In other embodiments, the absorber layer includes an absorber material having a low extinction coefficient and a high index of refraction. In accordance with some embodiments of the present disclosure, the index of refraction and the extinction coefficient are in relation to light having a wavelength of about 13.5 nm. In accordance with some embodiments, the thickness of absorber layer 140 is less than about 80 nm. In accordance with other embodiments, the thickness of absorber layer 140 is less than about 60 nm. Other embodiments utilize an absorber layer 140 that is less than about 50 nm.

In some embodiments, the absorber material is in a polycrystalline state characterized by grains, grain boundaries and different phases of formation. In other embodiments, the absorber material is in an amorphous state characterized by grains on the order of less than 5 nanometers or less than 3 nanometers, no grain boundaries, and a single phase. In accordance with some embodiments of the present disclosure, the absorber material includes interstitial elements selected from nitrogen (N), oxygen (O), boron (B), carbon (C), or combinations thereof. As used herein, interstitial elements refer to elements which are located at interstices between materials comprising a main alloy and an alloying element of absorber materials formed in accordance with the present disclosure.

The absorber layer 140 is formed by deposition techniques such as PVD, CVD, ALD, RF magnetron sputtering, DC magnetron sputtering, or IBD. The deposition process can be carried out in the presence of elements described as interstitial elements, such as B or N. Carrying out the deposition in the presence of the interstitial elements results in the interstitial elements being incorporated into the material of the absorber layer 140.

In accordance with embodiments of the present disclosure, multiple combinations of different families of alloy materials are useful as absorber materials. Each of the different families of different alloys includes a main alloy element selected from a transition metal and at least one alloying element. In accordance with some embodiments, the main alloy element comprises up to 90 atomic percent of the alloy used as an absorber material. In some embodiments, the main alloy element comprises more than 50 atomic percent of the alloy used as an absorber material. In some embodiments, the main alloy element comprises about 50 to 90 atomic percent of the alloy used as an absorber material.

In accordance with some embodiments, the main alloy element is a transition metal selected from ruthenium (Ru), chromium (Cr), tantalum (Ta), platinum (Pt), gold (Au), iridium (Ir), titanium (Ti), niobium (Nb), rhodium (Rh), molybdenum (Mo), tungsten (W), and palladium (Pd). In accordance with some embodiments, the at least one alloying element is a transition metal, metalloid, or reactive nonmetal. Examples of the at least one alloying element that is a transition metal include ruthenium (Ru), chromium (Cr), tantalum (Ta), platinum (Pt), palladium (Pd), tungsten (W), gold (Au), iridium (Ir), titanium (Ti), niobium (Nb), rhodium (Rh), molybdenum (Mo), hafnium (Hf), zirconium (Zr), and vanadium (V). Examples of the at least one alloying element that is a metalloid include boron (B) and silicon (Si). Examples of the at least one alloying element that is a reactive nonmetal includes nitrogen (N) or oxygen (O).

Different materials may be used to etch the different absorber materials of the present disclosure and different materials may be used as a hard mask layer with the different absorber materials. For example, in some embodiments, the absorber layer 140 is dry etched with a gas that contains chlorine, such as Cl₂ or BCl₃, or with a gas that contains fluorine, such as NF₃. Ar may be used as a carrier gas. In some embodiments, oxygen (O₂) may also be included as the carrier gas. For example, a chlorine-based etchant, chlorine-based plus oxygen etchant, or a mixture of a chlorine-based and fluorine-based (e.g., carbon tetrafluoride and carbon tetrachloride) etchant will etch the alloys that include a main alloy element comprising ruthenium (Ru), chromium (Cr), tantalum (Ta), platinum (Pt) or gold (Au), and at least one alloying element selected from ruthenium (Ru), chromium (Cr), tantalum (Ta), platinum (Pt), palladium (Pd), tungsten (W), gold (Au), iridium (Ir), niobium (Nb), rhodium (Rh), molybdenum (Mo), hafnium (Hf) or vanadium (V). In with some embodiments, a fluorine-based etchant is suitable to etch the alloys that include a main alloy element comprising iridium (Ir), titanium (Ti), niobium (Ni) or rhodium (Rh) and at least one alloying element selected from boron (B), nitrogen (N), oxygen (O), silicon (Si), tantalum (Ta), zirconium (Zr), niobium (Ni), molybdenum (Mo), rhodium (Rh), titanium (Ti) or ruthenium (Ru). In some embodiments, a fluorine-based or a fluorine-based plus oxygen etchant is suitable to etch the alloys that include a main alloy element comprising molybdenum (Mo), tungsten (W) or palladium (Pd) and at least one alloying element selected from ruthenium (Ru), palladium (Pd), tungsten (W), iridium (Ir), titanium (Ti), niobium (Nb), rhodium (Rh), molybdenum (Mo), silicon (Si) or zirconium (Zr).

In accordance with some embodiments, SiN, TaBO, TaO, SiO, SiON, and SiOB are examples of materials useful as hard mask layer 160 for absorber layer 140 utilizing alloys that include a main alloy element comprising ruthenium (Ru), chromium (Cr), tantalum (Ta), platinum (Pt) or gold (Au), and at least one alloying element selected from ruthenium (Ru), chromium (Cr), tantalum (Ta), platinum (Pt), palladium (Pd), tungsten (W), gold (Au), iridium (Ir), niobium (Nb), rhodium (Rh), molybdenum (Mo), hafnium (Hf) or vanadium (V). CrO and CrON are examples of materials useful for hard mask layer 160 for an absorber layer 140 that utilizes alloys that include a main alloy element comprising iridium (Ir), titanium (Ti), niobium (Ni) or rhodium (Rh) and at least one alloying element selected from boron (B), nitrogen (N), silicon (Si), tantalum (Ta), zirconium (Zr), niobium (Ni), molybdenum (Mo), rhodium (Rh), titanium (Ti) or ruthenium (Ru). SiN, TaBO, TaO, CrO, and CrON are examples of materials useful for hard mask layer 160 for an absorber layer 140 that utilizes alloys that include a main alloy element comprising molybdenum (Mo), tungsten (W) or palladium (Pd) and at least one alloying element selected from ruthenium (Ru), palladium (Pd), tungsten (W), iridium (Ir), titanium (Ti), niobium (Nb), rhodium (Rh), molybdenum (Mo), silicon (Si) or zirconium (Zr). In other embodiments, there may be a buffer layer (not shown) similar in composition to the hard mask layer between the multilayered capping feature 125 and the layer 140 of absorber material. In some embodiments, the material of the hard mask layer 160 is the same or different from the material of the buffer layer. Embodiments in accordance with the present invention are not limited to the foregoing types of materials for hard mask layer 160 or the buffer layer.

In some embodiments, the absorber layer 140 is deposited as an amorphous layer. By maintaining an amorphous phase, the overall roughness of the absorber layer 140 is improved. The thickness of the absorber layer 140 is controlled to provide between 95% and 99.5% absorption of the EUV light at 13.5 nm. In some embodiments, the absorber layer 140 may have a thickness ranging from about 5 nm to about 50 nm. If the thickness of the absorber layer 140 is too small, the absorber layer 140 is not able to absorb a sufficient amount of the EUV light to generate contrast between the reflective areas and non-reflective areas. On the other hand, if the thickness of the absorber layer 140 is too great, the precision of a pattern to be formed in the absorber layer 140 tends to be low.

Referring to FIGS. 2 and 3E, the method 200 proceeds to operation 210, in which a resist stack including a hard mask layer 160 and a photoresist layer 170 are deposited over the absorber layer 140, in accordance with some embodiments. FIG. 3E is a cross-sectional view of the structure of FIG. 3D after sequentially depositing the hard mask layer 160 and the photoresist layer 170 over the absorber layer 140, in accordance with some embodiments.

Referring to FIG. 3E, the hard mask layer 160 is disposed over the absorber layer 140. In some embodiments, the hard mask layer 160 is in direct contact with the absorber layer 140. In some embodiments, the hard mask layer 160 includes a dielectric oxide such as silicon dioxide or a dielectric nitride such as silicon nitride. In some embodiments, the hard mask layer 160 is formed using a deposition process such as, for example, CVD, PECVD, or PVD. In some embodiments, the hard mask layer 160 has a thickness ranging from about 2 to 10 nm. Embodiments in accordance with the present disclosure are not limited to hard mask layer 160 having a thickness ranging from about 2 to 10 nm.

The photoresist layer 170 is disposed over the hard mask layer 160. The photoresist layer 170 includes a photosensitive material operable to be patterned by radiation. In some embodiments, the photoresist layer 170 includes a positive-tone photoresist material, a negative-tone photoresist material or a hybrid-tone photoresist material. In some embodiments, the photoresist layer 170 is applied to the surface of the hard mask layer 160, for example, by spin coating.

Referring to FIGS. 2 and 3F, the method 200 proceeds to operation 212, in which the photoresist layer 170 is lithographically patterned to form a patterned photoresist layer 170P, in accordance with some embodiments. FIG. 3F is a cross-sectional view of the structure of FIG. 3E after lithographically patterning the photoresist layer 170 to form the patterned photoresist layer 170P, in accordance with some embodiments.

Referring to FIG. 3F, the photoresist layer 170 is patterned by first subjecting the photoresist layer 170 to a pattern of irradiation. Next, the exposed or unexposed portions of the photoresist layer 170 are removed, depending on whether a positive-tone or negative-tone resist is used in the photoresist layer 170, with a resist developer, thereby forming the patterned photoresist layer 170P having a pattern of openings 172 formed therein. The openings 172 expose portions of the hard mask layer 160. The openings 172 are located in the pattern region 100A and correspond to locations where the pattern of openings 152 are present in the EUV mask 100 (FIG. 1).

Referring to FIGS. 2 and 3G, the method 200 proceeds to operation 214, in which the hard mask layer 160 is etched using the patterned photoresist layer 170P as an etch mask to form a patterned hard mask layer 160P, in accordance with some embodiments. FIG. 3G is a cross-sectional view of the structure of FIG. 3F after etching the hard mask layer 160 to form the patterned hard mask layer 160P, in accordance with some embodiments.

Referring to FIG. 3G, portions of the hard mask layer 160 that are exposed by the openings 172 are etched to form openings 162 extending through the hard mask layer 160. The openings 162 expose portions of the underlying absorber layer 140. In some embodiments, the hard mask layer 160 is etched using an anisotropic etch using fluorine containing or chlorine containing gases such as CF₄, SF₆ or Cl₂. In some embodiments, the anisotropic etch is a dry etch such as, for example, reactive ion etch (RIE), a wet etch, or a combination thereof. The etch removes the material providing the hard mask layer 160 selective to the material providing the absorber layer 140. The remaining portions of the hard mask layer 160 constitute the patterned hard mask layer 160P. If not completely consumed during the etching of the hard mask layer 160, after etching the hard mask layer 160, the patterned photoresist layer 170P is removed from the surfaces of the patterned hard mask layer 160P, for example, using wet stripping or plasma ashing followed by a wet cleaning.

Referring to FIGS. 2 and 3H, the method 200 proceeds to operation 216, in which the absorber layer 140 is etched using the patterned hard mask layer 160P as an etch mask to form a patterned absorber layer 140P, in accordance with some embodiments. FIG. 3H is a cross-sectional view of the structure of FIG. 3G after etching the absorber layer 140 to form the patterned absorber layer 140P, in accordance with some embodiments.

Referring to FIG. 3H, portions of the absorber layer 140 that are exposed by the openings 162 are etched to form openings 142 extending through the absorber layer 140. The openings 142 expose portions of the second capping layer 130. In some embodiments, the absorber layer 140 is etched using an anisotropic etching process. In some embodiments, the anisotropic etch is a dry etch such as, for example, RIE, a wet etch, or a combination thereof that removes the material providing the absorber layer 140 selective to the material providing the underlying second capping layer 130. For example, in some embodiments, the absorber layer 140 is dry etched with a gas that contains chlorine, such as Cl₂ or BCl₃, or with a gas that contains fluorine, such as CF₄, SF₃ or NF₃. Ar may be used as a carrier gas. In some embodiments, oxygen (O₂) may also be included as the carrier gas. The etch rate and the etch selectivity depend on the etchant gas, etchant flow rate, power, pressure, and substrate temperature. After etching, the remaining portions of the absorber layer 140 constitute the patterned absorber layer 140P. In accordance with embodiments of the present disclosure, when absorber layer 140 includes multiple layers of absorber material, when the individual layers of absorber material have differential etching properties, the individual layers of absorber material may be etched individually using different etchants. When the individual layers of absorber material do not have differential etching properties, the individual layers of absorber for material may be etched simultaneously.

In some embodiments, etching of absorber layer 140 also removes a portion of the second capping layer 130. In other embodiments, etching of absorber layer 140 does not remove any of the second capping layer 130. In cases where etching of the absorber layer 140 removes a portion of the second capping layer 130 or etching of the absorber layer 140 does not remove any of the second capping layer 130, etching of the second capping layer 130 proceeds at operation 218. Referring to FIGS. 2 and 3I, the method 200 proceeds to operation 218, in which the second capping layer 130 is etched using the patterned hard mask layer 160P and patterned absorber layer 140P as an etch mask to form a patterned second capping layer 130P, in accordance with some embodiments. FIG. 3I is a cross-sectional view of the structure of FIG. 3H after etching the second capping layer 130 to form the patterned second capping layer 130P and removal of patterned hard mask 160P, in accordance with some embodiments.

Referring to FIG. 3I, portions of the second capping layer 130 that are exposed by the openings 162 and 142 are etched to form openings 132 extending through the second capping layer 130. The openings 132 expose portions of the underlying first capping layer 120 at the bottom of trenches formed in the absorber layer 140 and second capping layer 130. In some embodiments, the second capping layer 130 is etched using an anisotropic etching process. In some embodiments, the anisotropic etch is a dry etch such as, for example, RIE, a wet etch, or a combination thereof that removes the material providing the second capping layer 130 selectively to the material providing the first capping layer 120. In some embodiments, the second capping layer 130 is etched using a gas that contains chlorine such as Cl₂ or BCl₃, or a gas that contains fluorine, such as CF₄, SF₃ or NF₃. The remaining portions of the capping layer 130 constitute the patterned second capping layer 130P. After etching the second capping layer 130, the patterned hard mask layer 160P is removed from the surfaces of the patterned absorber layer 140P, for example, using oxygen plasma or a wet etch.

In accordance with some embodiments, the etching of the second capping layer 130 is selective such that etching of second capping layer 130 does not remove any portion of the underlying first capping layer 120. In other embodiments, the etching of the second capping layer 130 does remove a portion of the underlying first capping layer 120. In such situations, etching of the underlying first capping layer 120 is controlled such that a sufficient thickness of first capping layer number 120 remains to impede or prevent the formation of carbon on the first capping layer 120.

The openings 142 in the patterned absorber layer 140P and respective underlying openings 132 in the patterned second capping layer 130P together define the pattern of openings 152 in the EUV mask 100. In accordance with embodiments of the present disclosure, the portions of patterned first capping layer 120 that are exposed through patterned second capping layer 130 exhibit a reduce susceptibility to deposition or contamination with carbon.

Referring to FIGS. 2 and 3J, the method 200 proceeds to operation 220, in which a patterned photoresist layer 180P comprising a pattern of openings 182 is formed over the patterned absorber layer 140P and the first capping layer 120, in accordance with some embodiments. FIG. 2J is a cross-sectional view of the structure of FIG. 3I after forming the patterned photoresist layer 180P comprising openings 182 over the patterned absorber layer 140P and the first capping layer 120, in accordance with some embodiments.

Referring to FIG. 3J, the openings 182 expose portions of the patterned absorber layer 140P at the periphery of the patterned absorber layer 140P. The openings 182 correspond to the trenches 154 in the peripheral region 100B of the EUV mask 100 that are to be formed. To form the patterned photoresist layer 180P, a photoresist layer (not shown) is applied over the first capping layer 120 and the patterned absorber layer 140P. The photoresist layer fills the openings 132 and 142 in the patterned second capping layer 130P and the patterned absorber layer 140P, respectively. In some embodiments, the photoresist layer includes a positive-tone photoresist material, a negative-tone photoresist material, or a hybrid-tone photoresist material. In some embodiments, the photoresist layer includes a same material as the photoresist layer 170 described above in FIG. 3D. In some embodiments, the photoresist layer includes a different material from the photoresist layer 170. In some embodiments, the photoresist layer is formed, for example, by spin coating. A photoresist layer 180 is subsequently patterned by exposing the photoresist layer 180 to a pattern of radiation, and removing the exposed or unexposed portions of the photoresist layer using a resist developer depending on whether a positive or negative resist is used. The remaining portions of the photoresist layer 180 constitute the patterned photoresist layer 180P.

Referring to FIGS. 2 and 3K, the method 200 proceeds to operation 222, in which the patterned absorber layer 140P, the patterned second capping layer 130P, the first capping layer 120, and the reflective multilayer stack 110 are etched using the patterned photoresist layer 180P as an etch mask to form trenches 154 in the peripheral region 100B of the substrate 102, in accordance with some embodiments. FIG. 3K is a cross-sectional view of the structure of FIG. 3J after etching the patterned absorber layer 140P, the patterned second capping layer 130P, the first capping layer 120, and the reflective multilayer stack 110, to form the trenches 154 in the peripheral region 100B of the substrate 102, in accordance with some embodiments.

Referring to FIG. 3K, the trenches 154 extend through the patterned absorber layer 140P, the patterned second capping layer 130P, the first capping layer 120, and the reflective multilayer stack 110 to expose the surface of the substrate 102. The trenches 154 surround the pattern region 100A of the EUV mask 100, separating the pattern region 100A from the peripheral region 100B.

In some embodiments, the patterned absorber layer 140P, the patterned second capping layer 130P, the first capping layer 120, and the reflective multilayer stack 110 are etched using a single anisotropic etching process. The anisotropic etch can be a dry etch such as, for example, RIE, a wet etch, or a combination thereof that removes materials of the respective patterned absorber layer 140P, the patterned second capping layer 130P, the first capping layer 120, and the reflective multilayer stack 110, selective to the material providing the substrate 102. In some embodiments, the patterned absorber layer 140P, the patterned second capping layer 130P, the first capping layer 120, and the reflective multilayer stack 110 are etched using multiple distinct anisotropic etching processes. Each anisotropic etch can be a dry etch such as, for example, RIE, a wet etch, or a combination thereof.

Referring to FIGS. 2 and 3L, the method 200 proceeds to operation 224, in which the patterned photoresist layer 180P is removed, in accordance with some embodiments. FIG. 3L is a cross-sectional view of the structure of FIG. 3K after removing the patterned photoresist layer 180P, in accordance with some embodiments.

Referring to FIG. 3L, the patterned photoresist layer 180P is removed from the pattern region 100A and the peripheral region 100B of the substrate 102, for example, by wet stripping or plasma ashing. The removal of the patterned photoresist layer 180P from the openings 142 in the patterned absorber layer 140P and the openings 132 in the patterned second capping layer 130P re-exposes the surfaces of the first capping layer 120 in the pattern region 100A.

An EUV mask 100 is thus formed. The EUV mask 100 includes a substrate 102, a reflective multilayer stack 110 over a front surface of the substrate 102, a first patterned capping layer 120P over the reflective multilayer stack 110, a patterned second capping layer 130P over the first patterned capping layer 120P, and a patterned absorber layer 140P over the patterned second capping layer 130P. The EUV mask 100 further includes a conductive layer 104 over a back surface of the substrate 102 opposite the front surface. In accordance with embodiments of the present disclosure, the first capping layer 120 protects the EUV mask from carbon contamination by reducing or preventing deposition, formation or absorption of carbon onto exposed surfaces of the first capping layer 120. As a result, the detrimental effects (e.g., need for increased EUV energy or negative effects on CDU) from carbon formation on or carbon contamination of an EUV mask are reduced or prevented and a pattern on the EUV mask 100 can be projected precisely onto a silicon wafer.

After removal of the patterned photoresist layer 180P, the EUV mask 100 is cleaned to remove any contaminants therefrom. In some embodiments, the EUV mask 100 is cleaned by submerging the EUV mask 100 into an ammonium hydroxide (NH₄OH) solution. In some embodiments, the EUV mask 100 is cleaned by submerging the EUV mask 100 into a diluted hydrofluoric acid (HF) solution.

The EUV mask 100 is subsequently radiated with, for example, an UV light with a wavelength of 193 nm, for inspection of any defects in the patterned region 100A. The foreign matters may be detected from diffusely reflected light. If defects are detected, the EUV mask 100 is further cleaned using suitable cleaning processes.

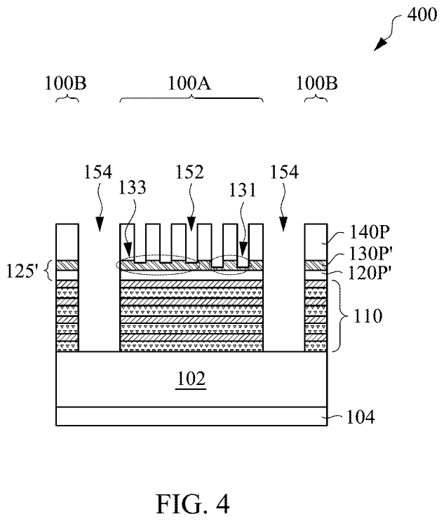

FIG. 4 is a cross-sectional view of an EUV mask 400, in accordance with a second embodiment of the present disclosure. EUV mask 400 is similar in some regards to EUV mask 100 described above with respect to FIGS. 1-3. Accordingly structures and features which are common between EUV mask 400 and EUV mask 100 are identified by the same reference numerals and the description above applies to those features. Referring to FIG. 4, the EUV mask 400 includes a substrate 102, a reflective multilayer stack 110 over a front surface of the substrate 102, a patterned first capping layer 120P′ over the reflective multilayer stack 110, a patterned second capping layer 130P′ and a patterned absorber layer 140P over the second patterned capping layer 130P′. The composition of patterned first capping 120P′ of EUV mask 400 differs from the composition of patterned first capping layer 120P of EUV mask 100 and the composition of patterned second capping layer 130P′ differs from the composition of the patterned second capping layer 130P of EUV mask 100. In accordance with embodiments of the present disclosure relative to FIG. 4, the description above regarding the composition of the second capping layer 130 applies to the patterned first capping layer 120P′ and the description above regarding the first capping layer 120 applies to the patterned second capping layer 130P′. In other words, the position of the first capping layer 120 and the second capping layer 130 of the embodiments of FIG. 1 are reversed to provide embodiments in accordance with FIG. 4. The EUV mask 400 further includes a conductive layer 104 over a back surface of the substrate 102 opposite the front surface. While the embodiment of FIG. 4 is illustrated and described with reference to a multilayered capping feature 125 that includes two capping layers, embodiments of the present disclosure include EUV masks that include a multilayered capping feature including more than two capping layers.

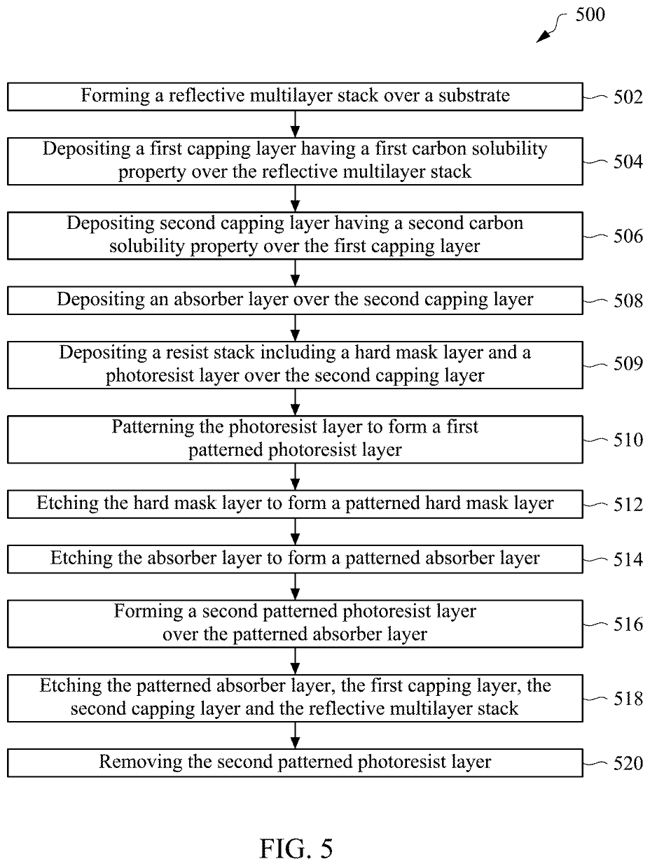

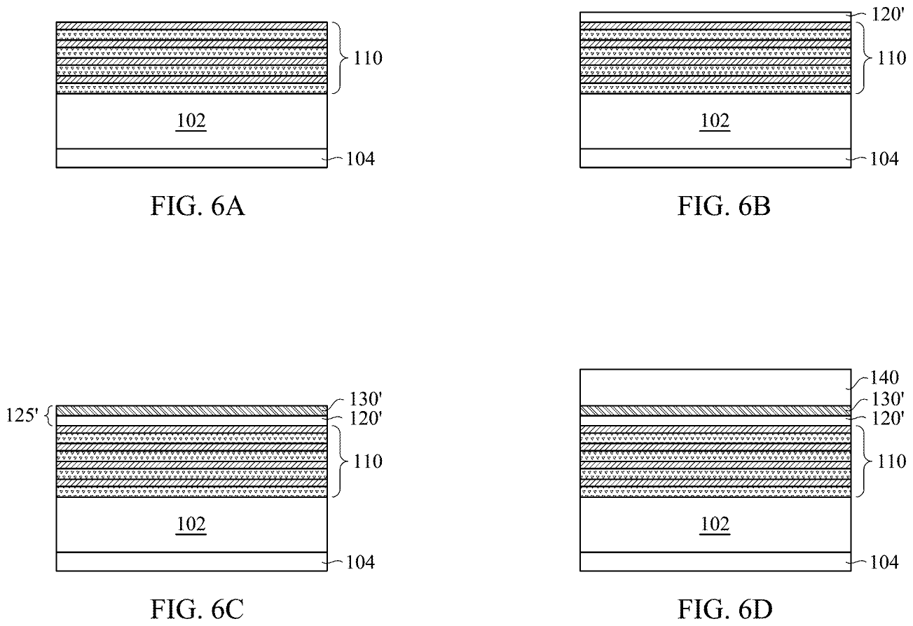

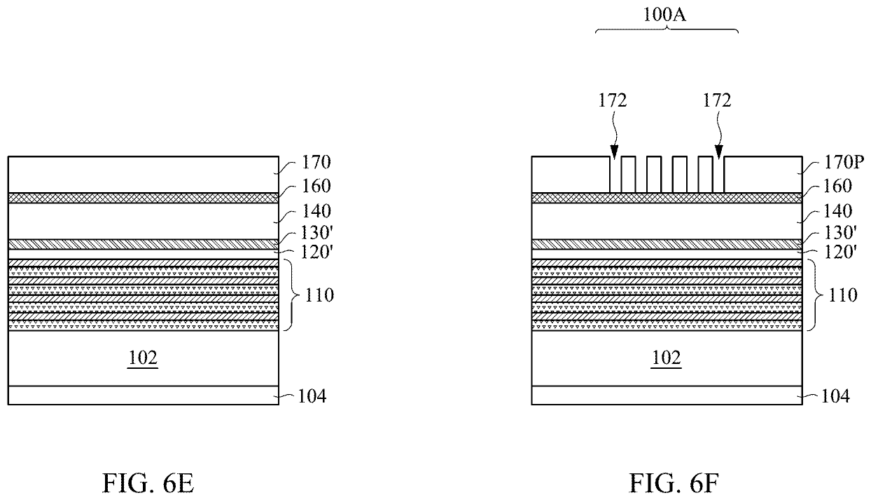

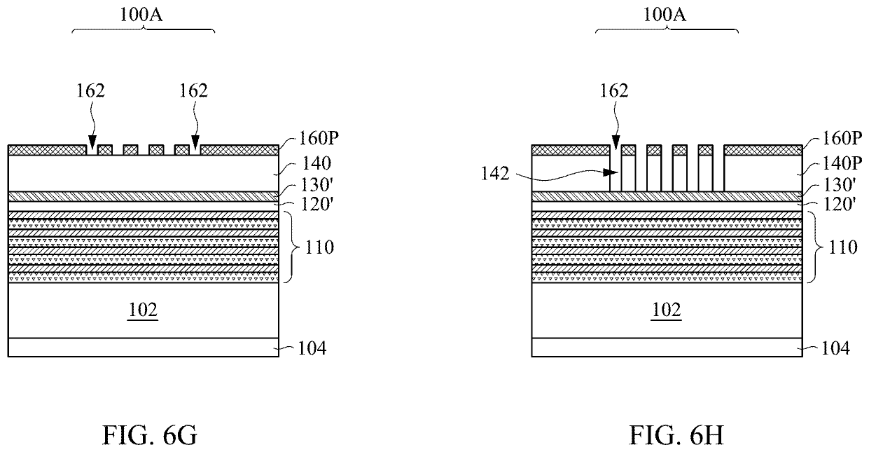

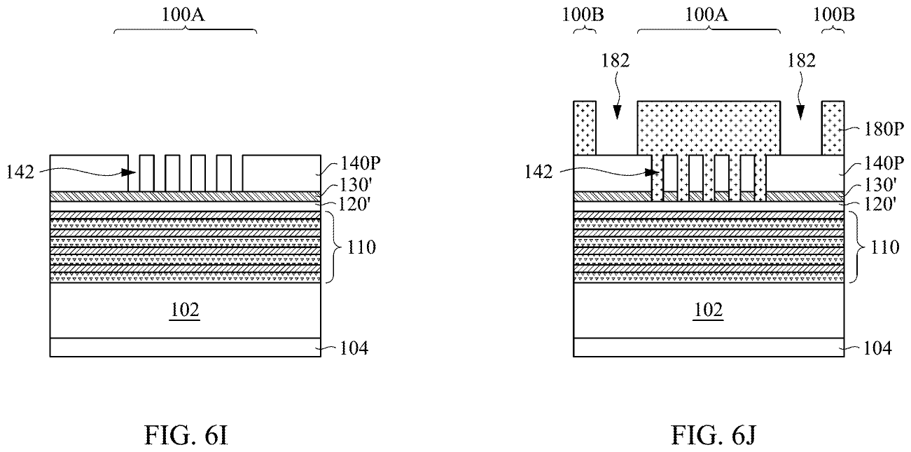

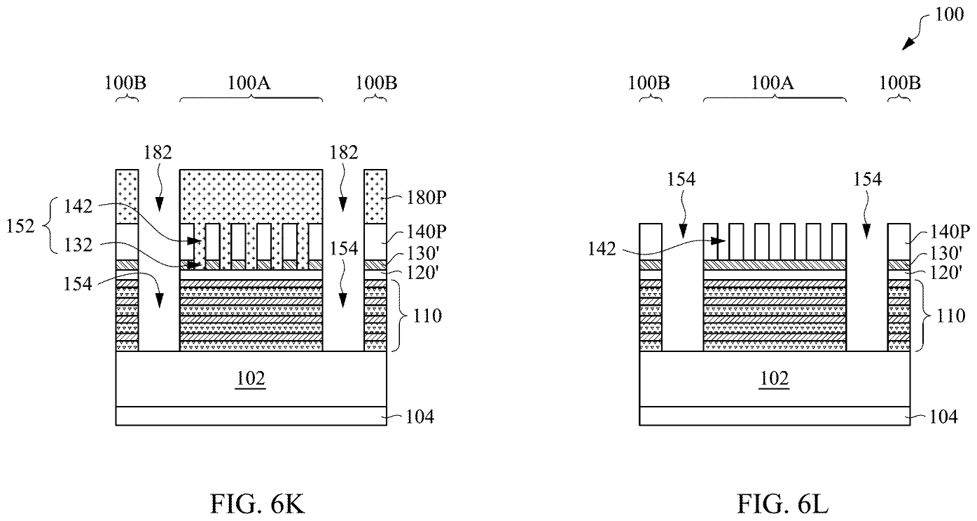

FIG. 5 is a flowchart of a method 500 for fabricating an EUV mask, for example, EUV mask 400, in accordance with some embodiments. FIG. 6A through FIG. 6L are cross-sectional views of the EUV mask 400 at various stages of the fabrication process, in accordance with some embodiments. The method 500 is discussed in detail below, with reference to the EUV mask 400. In some embodiments, additional operations are performed before, during, and/or after the method 500, or some of the operations described are replaced and/or eliminated. In some embodiments, some of the features described below are replaced or eliminated. One of ordinary skill in the art would understand that although some embodiments are discussed with operations performed in a particular order, these operations may be performed in another logical order.

Referring to FIGS. 5 and 6A, the method 500 includes operation 502, in which a reflective multilayer stack 110 is formed over a substrate 102, in accordance with some embodiments. FIG. 6A is a cross-sectional view of an initial structure of an EUV mask 400 after forming the reflective multilayer stack 110 over the substrate 102, in accordance with some embodiments. The materials and formation processes for the reflective multilayer stack 110 are similar to those described above in FIG. 3A, and hence are not described in detail herein.

Referring to FIGS. 5 and 6B, the method 500 proceeds to operation 504, in which a first capping layer 120′ is deposited over the reflective multilayer stack 110, in accordance with some embodiments. FIG. 6B is a cross-sectional view of the structure of FIG. 6A after depositing the first capping layer 120′ over the reflective multilayer stack 110, in accordance with some embodiments. The materials and formation processes for the first capping layer 120′ are similar to those described above with respect to the materials and formation of second capping layer 130 in FIG. 3C, and hence are not described in detail herein.

Referring to FIGS. 5 and 6C, the method 500 proceeds to operation 506, in which a second capping layer 130′ is deposited over the first capping layer 120′, in accordance with some embodiments. FIG. 6C is a cross-sectional view of the structure of FIG. 6B after depositing the second capping layer 130′ over the first capping layer 120′, in accordance with some embodiments. In the embodiment of FIG. 6C, first capping layer 120′ and second capping layer 130′ comprise the multilayered capping feature 125′. The materials and formation processes for the second capping layer 130′ are similar to those described above with respect to the materials and formation of first capping layer 120 in FIG. 3C, and hence are not described in detail herein.

Referring to FIGS. 5 and 6D, the method 500 proceeds to operation 508, in which an absorber layer 140 is deposited over the second capping layer 130′, in accordance with various embodiments. FIG. 6D is a cross-sectional view of the structure of FIG. 6C after depositing the absorber layer 140 over the second capping layer 130′, in accordance with some embodiments. The materials and formation processes for the absorber layer 140 are similar to those described above in FIG. 3D, and hence are not described in detail herein.

Referring to FIGS. 5 and 6E, the method 500 proceeds to operation 509, in which a resist stack including a hard mask layer 160 and a photoresist layer 170 is deposited over the absorber layer 140, in accordance with some embodiments. FIG. 6E is a cross-sectional view of the structure of FIG. 6D after sequentially depositing the hard mask layer 160 and the photoresist layer 170 over the absorber layer 140, in accordance with some embodiments. Materials and formation processes for respective hard mask layer 160 and photoresist layer 170 are similar to those described in FIG. 3E, and hence are not described in detail herein.

Referring to FIGS. 5 and 6F, the method 500 proceeds to operation 510, in which the photoresist layer 170 is lithographically patterned to form a patterned photoresist layer 170P, in accordance with some embodiments. FIG. 6F is a cross-sectional view of the structure of FIG. 6E after lithographically patterning the photoresist layer 170 to form the patterned photoresist layer 170P, in accordance with some embodiments. Etching processes for the photoresist layer 170 are similar to those described in FIG. 3F, and hence are not described in detail herein.

Referring to FIGS. 5 and 6G, the method 500 proceeds to operation 512, in which the hard mask layer 160 is etched using the patterned photoresist layer 170P as an etch mask to form a patterned hard mask layer 160P, in accordance with some embodiments. FIG. 6G is a cross-sectional view of the structure of FIG. 6F after etching the hard mask layer 160 to form the patterned hard mask layer 160P, in accordance with some embodiments. Etching processes for the hard mask layer 160 are similar to those described in FIG. 3G, and hence are not described in detail herein.

Referring to FIGS. 5 and 6H, the method 500 proceeds to operation 514, in which the absorber layer 140 is etched using the patterned hard mask layer 160P as an etch mask to form a patterned absorber layer 140P, in accordance with some embodiments. FIG. 6H is a cross-sectional view of the structure of FIG. 6G after etching the absorber layer 140 to form the patterned absorber layer 140P, in accordance with some embodiments. Etching processes for the absorber layer 140 are similar to those described in FIG. 3H, and hence are not described in detail herein. The patterned absorber layer 140P includes a plurality of openings 142 that expose the underlying second capping layer 130′. After etching the absorber layer 140, the patterned hard mask layer 160P is removed from the surfaces of the patterned absorber layer 140P, for example, using oxygen plasma or a wet etch. The resulting structure is illustrated in FIG. 6I.

In some embodiments in accordance FIGS. 4-6, the steps of etching absorber layer 140 to form patterned absorber layer 140P and/or the step of removing the photoresist layer 170 and/or patterned hard mask layer 160P can remove portions of an upper surface of second capping layer 130′. Such embodiments are illustrated in FIG. 4 by reference number 131 where a portion of patterned second capping layer 130P′ is removed by the step of etching absorber layer 140 or the step of removing the photoresist layer 170 and/or patterned hard mask layer 160P. In accordance with embodiments where a portion of an upper surface of patterned second capping layer 130P′ is removed, the an amount of the upper surface of patterned second capping layer 130P′ remains, e.g., at least a few nanometers of patterned second capping layer 130P′ remains. Examples of a few nanometers includes 1 to 2 nm. In other embodiments in accordance with FIGS. 4-6, the steps of etching absorber layer 140 to form patterned absorber layer 140P and/or the step of removing the photoresist layer 170 and/or patterned hard mask layer 160P do not remove portions of second capping layer 130′. Such embodiments are illustrated in FIG. 4 by reference number 133. FIG. 6I illustrates an embodiment wherein none of second capping layer 130′ has been removed by the absorber layer, photoresist or hard mask removal steps.

Referring to FIGS. 5 and 6J, the method 500 proceeds to operation 516, in which a patterned photoresist layer 180P comprising a pattern of openings 182 is formed over the patterned absorber layer 140P and second capping layer 130′, in accordance with some embodiments. FIG. 6J is a cross-sectional view of the structure of FIG. 6I after forming the patterned photoresist layer 180P comprising openings 182 over the patterned absorber layer 140P and second capping layer 130′, in accordance with some embodiments. Materials and fabrication processes for the patterned photoresist layer 180P are similar to those described in FIG. 3J, and hence are not described in detail herein.

Referring to FIGS. 5 and 6K, the method 500 proceeds to operation 518, in which the patterned absorber layer 140P, the second capping layer 130′, the first capping layer 120′, and the reflective multilayer stack 110 are etched using the patterned photoresist layer 180P as an etch mask to form trenches 154 in the peripheral region 100B of the substrate 102, in accordance with some embodiments. FIG. 6K is a cross-sectional view of the structure of FIG. 6J after etching the patterned absorber layer 140P, the second capping layer 130′, the first capping layer 120′ and the reflective multilayer stack 110, to form the trenches 154 in the peripheral region 100B of the substrate 102, in accordance with some embodiments.

Referring to FIG. 6K, the trenches 154 extend through the patterned absorber layer 140P, the second capping layer 130′, the first capping layer 120′ and the reflective multilayer stack 110 to expose the surface of the substrate 102. The trenches 154 surround the pattern region 100A of the EUV mask 100, separating the pattern region 100A from the peripheral region 100B.

In some embodiments, the patterned absorber layer 140P, the second capping layer 130′, the first capping layer 120′, and the reflective multilayer stack 110 are etched using a single anisotropic etching process. The anisotropic etch can be a dry etch such as, for example, ME, a wet etch, or a combination thereof that removes materials of the respective patterned absorber layer 140P, the second capping layer 130′, the first capping layer 120′ and the reflective multilayer stack 110, selective to the material providing the substrate 102. In some embodiments, the patterned absorber layer 140P, the second capping layer 130′, the first capping layer 120′ and the reflective multilayer stack 110 are etched using multiple distinct anisotropic etching processes. Each anisotropic etch can be a dry etch such as, for example, RIE, a wet etch, or a combination thereof.

Referring to FIGS. 5 and 6L, the method 500 proceeds to operation 520, in which the patterned photoresist layer 180P is removed, in accordance with some embodiments. FIG. 6L is a cross-sectional view of the structure of FIG. 6K after removing the patterned photoresist layer 180P, in accordance with some embodiments.

Referring to FIG. 6L, the patterned photoresist layer 180P is removed from the pattern region 100A and the peripheral region 100B of the substrate 102, for example, by wet stripping or plasma ashing. The removal of the patterned photoresist layer 180P from the openings 142 in the patterned absorber layer 140P re-exposes the surfaces of the second capping layer 130′ in the pattern region 100A. The openings 142 in the patterned absorber layer 140P define the pattern of openings in the EUV mask 400 that correspond to circuit patterns to be formed on a semiconductor wafer.

An EUV mask 400 is thus formed. The EUV mask 400 includes a substrate 102, a reflective multilayer stack 110 over a front surface of the substrate 102, a first patterned capping layer 120P′ over the reflective multilayer stack 110, a second patterned capping layer 130P′ over the first patterned capping layer 120P′ and a patterned absorber layer 140P over the second patterned capping layer 130P′. The EUV mask 400 further includes a conductive layer 104 over a back surface of the substrate 102 opposite the front surface. In accordance with embodiments of FIGS. 4-6, the second capping layer 130′ protects the underlying first capping layer 120′ and reflective multilayer stack 110 from carbon contamination by reducing or preventing deposition, formation or absorption of carbon onto exposed surfaces of the second capping layer 130′. As a result, the detrimental effects (e.g., need for increased EUV energy or negative effects on CDU) from carbon formation on or carbon contamination of an EUV mask are reduced or prevented and a pattern on the EUV mask 100 can be projected precisely onto a silicon wafer.

After removal of the patterned photoresist layer 180P, the EUV mask 400 is cleaned to remove any contaminants therefrom. In some embodiments, the EUV mask 400 is cleaned by submerging the EUV mask 400 into an ammonium hydroxide (NH₄OH) solution. In some embodiments, the EUV mask 400 is cleaned by submerging the EUV mask 400 into a diluted hydrofluoric acid (HF) solution.

The EUV mask 400 is subsequently radiated with, for example, an UV light with a wavelength of 193 nm, for inspection of any defects in the patterned region 100A. The foreign matters may be detected from diffusely reflected light. If defects are detected, the EUV mask 400 is further cleaned using suitable cleaning processes.

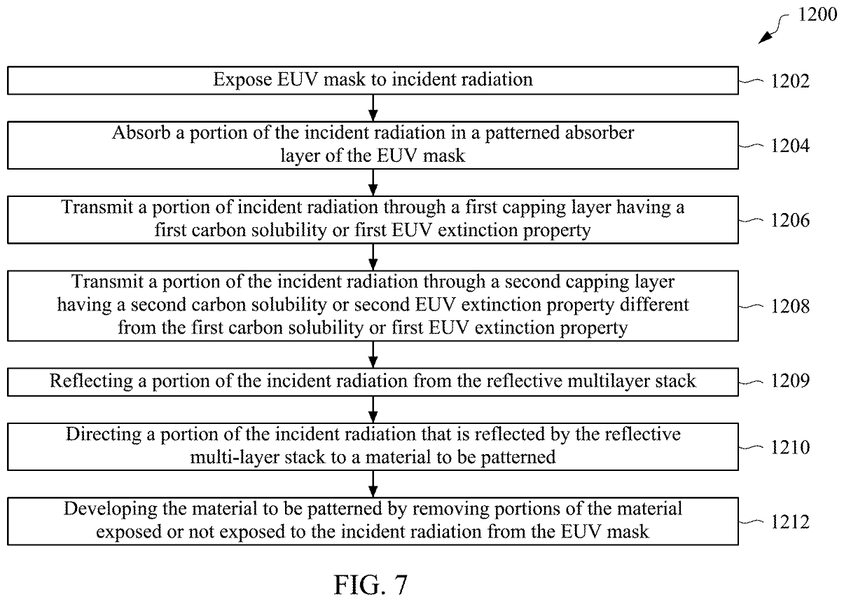

FIG. 7 illustrates a method F of using an EUV mask in accordance with embodiments of the present disclosure. Method 1200 includes step 1202 of exposing an EUV mask to an incident radiation, e.g., EUV radiation. An example of an EUV mask useful in step 1202 includes the EUV masks 100 or 400 described above. At step 1204, a portion of the incident radiation is absorbed in a patterned absorber layer of the EUV mask. At step 1206, a portion of the incident radiation is transmitted through a capping layer having a first carbon solubility or EUV extinction property. An example of a capping layer having a first carbon solubility or EUV extinction property includes the second capping layers 130 and 130′ described above. At step 1208, a portion of the incident radiation is transmitted through a capping layer having a second carbon solubility or EUV extinction property that is different from the first carbon solubility or EUV extinction property. Examples of capping layers having a second carbon solubility or EUV extinction property include the first capping layers 120 and 120′ described above. At step 1209, a portion of the incident radiation is reflected from the reflective multilayer stack. A portion of the incident radiation that is reflected by the reflective multilayer stack is directed to a material to be patterned in step 1210. The reflected incident radiation will be transmitted back through the first capping layer and the second capping layer on its path to the material to be patterned. After the material to be patterned has been exposed to the radiation reflected from the EUV mask, portions of the material exposed or not exposed to the radiation reflected from the EUV mask are removed at step 1212.

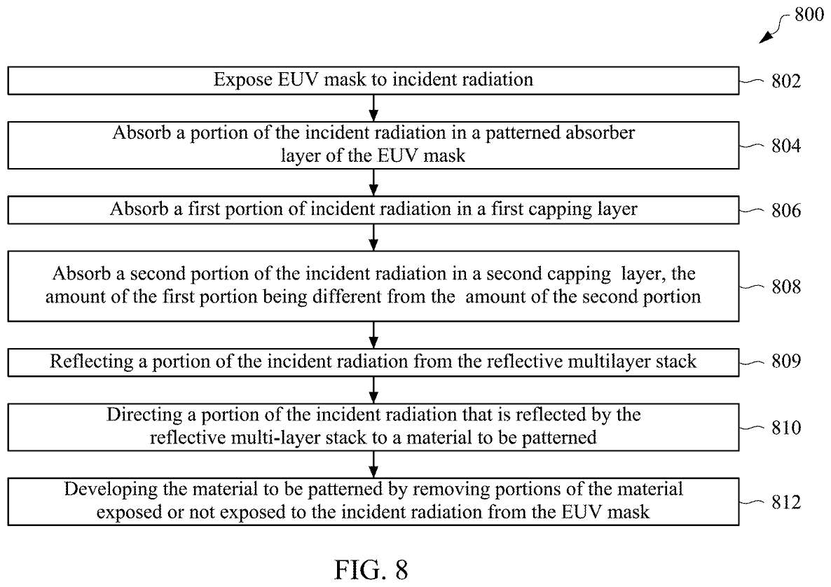

FIG. 8 illustrates a method 800 of using an EUV mask in accordance with embodiments of the present disclosure. Method 800 includes step 802 of exposing an EUV mask to an incident radiation, e.g., EUV radiation. An example of an EUV mask useful in step 802 includes the EUV masks 100 or 400 described above. At step 804, a portion of the incident radiation is absorbed in a patterned absorber layer of the EUV mask. At step 806, an amount of a first portion of the incident radiation is absorbed in the first capping layer. An example of a capping layer having a first carbon solubility or EUV extinction property includes the second capping layers 130 and 130′ described above. At step 808, an amount of a second portion of the incident radiation is absorbed by a second capping layer. In this embodiment, the amount of the first portion of incident radiation absorbed by the first capping layer is different from the amount of incident radiation absorbed by the second capping layer. Examples of second capping layer include the first capping layers 120 and 120′ described above. At step 809, a portion of the incident radiation is reflected from the reflective multilayer stack. A portion of the incident radiation that is reflected by the reflective multilayer stack is directed to a material to be patterned in step 810. The reflected incident radiation will be transmitted back through the first capping layer and the second capping layer on its path to the material to be patterned. After the material to be patterned has been exposed to the radiation reflected from the EUV mask, portions of the material exposed or not exposed to the radiation reflected from the EUV mask are removed at step 812.

One aspect of this description relates to an EUV mask. The EUV mask includes a substrate, a reflective multilayer stack on the substrate, and a multilayer capping feature on the reflective multilayer stack. The multilayer capping feature includes a first capping layer including material having a first carbon solubility and a second capping layer including a material having a second carbon solubility. The first carbon solubility is different from the second carbon solubility. The EUV mask also includes a patterned absorber layer on the multilayer capping feature. In other embodiments, the first capping layer includes a material having an extinction coefficient for EUV radiation having a wavelength of 13.5 nm that is different from an extinction coefficient for EUV radiation having a wavelength of 13.5 nm of the material of the second capping layer. Such EUV masks exhibit a reduced propensity to carbon build up or contamination which can negatively affect the ability of the mask to produce patterns that satisfy critical dimension criteria.

Another aspect of this description relates to relates to a method of using an EUV mask. The method includes exposing an EUV mask to an incident radiation. The EUV mask includes a substrate, a reflective multi-stack on the substrate and a multilayer capping feature on the reflective multilayer stack. The multilayer capping feature includes a first capping layer having a first EUV extinction coefficient and a second capping layer having a second EUV extinction coefficient, the first EUV extinction coefficient being different from the second EUV extinction coefficient. The EUV mask includes a patterned absorber layer on the multilayer capping feature. The method includes absorbing a portion of the incident radiation in the patterned absorber layer. A portion of the incident radiation is transmitted through the first capping layer and the second capping layer. A portion of the incident radiation is reflected from the reflective multilayer stack and directed to a material to be patterned.

Still another aspect of this description relates to another method of using an EUV mask. The method includes exposing the EUV mask to an incident radiation. The EUV mask includes a substrate, a reflective multi-stack layer on the substrate, a multilayer capping feature and a patterned absorber layer on the multilayer capping feature. The multilayer capping feature includes a first capping layer and a second capping layer. The method further includes absorbing a portion of incident radiation in the patterned absorber layer. In the method, a first amount of a first portion of the incident radiation is absorbed in the first capping layer and a second amount of a second portion of the incident radiation is absorbed in the second capping layer. The first amount being different from the second amount. The method proceeds with reflecting a portion of the incident radiation from the reflective multi-stack layer and directing it to a material to be patterned.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An extreme ultraviolet (EUV) mask, comprising:
a substrate;
a reflective multilayer stack on the substrate;
a multi-layer capping feature on the reflective multilayer stack, the multi-layer capping feature including a first capping layer including a material containing an element having a first solid carbon solubility and a second capping layer including a material containing an element having a second solid carbon solubility, the first carbon solubility being different from the second carbon solubility; and
a patterned absorber layer on the multi-layer capping feature.

2. The EUV mask of claim 1, wherein the first solid carbon solubility is less than the second solid carbon solubility.

3. The EUV mask of claim 2, wherein the first solid carbon solubility of the element of the material of the first capping layer at 1000° C. is less than 1.6 atomic percent.

4. The EUV mask of claim 1, wherein the second solid carbon solubility of the element of the material of the second capping layer at 1000° C. is less than the first solid carbon solubility of the element of the material of the first capping layer at 1000° C.

5. The EUV mask of claim 1, wherein an element of the material of the first capping layer has an EUV extinction coefficient for EUV radiation having a wavelength of 13.5 nm that is different from the EUV extinction coefficient for EUV radiation having a wavelength of 13.5 nm of an element of the material of the second capping layer.

6. The EUV mask of claim 5, wherein the EUV extinction coefficient for EUV radiation having a wavelength of 13.5 nm of the element of the material of the first capping layer is between 0 and 0.1.

7. The EUV mask of claim 5, wherein the EUV extinction coefficient for EUV radiation having a wavelength of 13.5 nm of the element of the material of the second capping layer is between 0 and 0.1.

8. The EUV mask of claim 1, wherein the first solid carbon solubility of the first capping layer at 1000° C. is less than 1.6 atomic %.

9. The EUV mask of claim 1, wherein the second carbon solubility of the second capping layer at 1000° C. is less than 1.6 atomic %.

10. The EUV mask of claim 1, wherein the material of the first capping layer is selected from Cr, Rh, Zn, Zr, Ag, Cd or alloys thereof.

11. The EUV mask of claim 1, wherein the material of the second capping layer is selected from Cr, Rh, Zn, Zr, Ag, Cd or alloys thereof.

12. The EUV mask of claim 1, where portions of the first capping layer are exposed in trenches of the patterned absorber layer and second capping layer.

13. The EUV mask of claim 1, where portions of the second capping layer are exposed in trenches of the patterned absorber layer and no portions of the first capping layer are exposed in the trenches of the patterned absorber layer.

14. A method of lithographically patterning a material, the method comprising:
forming a material to be patterned on a workpiece;
exposing the EUV mask to an incident radiation, the EUV mask including:
a substrate;
a reflective multilayer stack on the substrate;
a multi-layer capping feature on the reflective multilayer stack, the multi-layer capping feature including a first capping layer including an element having a first EUV extinction coefficient for EUV radiation having a wavelength of 13.5 nm and a second capping layer including an element having a second EUV extinction coefficient for EUV radiation having a wavelength of 13.5 nanometers, the first EUV extinction coefficient being different from the second EUV extinction coefficient; and
a patterned absorber layer on the multi-layer capping feature;
absorbing a portion of the incident radiation in the patterned absorber layer;
transmitting a portion of the incident radiation through the first capping layer and the second capping layer;
reflecting a portion of the incident radiation from the reflective multilayer stack;
directing a portion of the incident radiation that is reflected by the reflective multilayer stack to the material to be patterned on the workpiece; and
developing the material to be patterned.

15. The method of claim 14, wherein the EUV extinction coefficient for EUV radiation having a wavelength of 13.5 nm of the element of the first capping layer is between 0 and 0.1.

16. The method of claim 14, wherein the EUV extinction coefficient for EUV radiation having a wavelength of 13.5 nm of the element of the second capping layer is between 0 and 0.1.

17. A method of using an extreme ultraviolet (EUV) mask, comprising:
exposing the EUV mask to an incident radiation, the EUV mask including:
a substrate;
a reflective multilayer stack on the substrate;
a multi-layer capping feature on the reflective multilayer stack, the multi-layer capping feature including a first capping layer and a second capping layer; and
a patterned absorber layer on the multi-layer capping feature;
absorbing a portion of the incident radiation in the patterned absorber layer;
absorbing a first amount of a first portion of the incident radiation in the first capping layer;
absorbing a second amount of a second portion of the incident radiation in the second capping layer, the first amount being different from the second amount;
reflecting a portion of the incident radiation from the reflective multilayer stack; and
directing a portion of the incident radiation that is reflected by the reflective multilayer stack to a material to be patterned.

18. The method of claim 17, wherein the first capping layer includes a material including an element having a first carbon solubility at 1000° C. that is less than a second carbon solubility at 1000° C. of an element of a material of the second capping layer.

19. The method of claim 17, wherein the second capping layer includes a material including an element having a second carbon solubility at 1000° C. that is less than a first carbon solubility at 1000° C. of an element of a material of the first capping layer.

20. The method of claim 17, wherein at least one of the first capping or the second capping layer includes Cr, Rh, Zn, Zr, Ag, Cd or alloys thereof.
